(19) United States
(12) Patent Application Publication
(10) Pub. No.: US 2026/0052851 A1
(43) Pub. Date: Feb. 19, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Xiaoxi SUN, Hefei (CN); Yingyu FENG, Kunshan (CN); Bo RAO, Hefei (CN); Yongqiang DU, Hefei (CN); Yuan YAO, Hefei (CN)

(73) Assignees: Hefei Visionox Technology Co., Ltd., Hefei (CN); Visionox Technology Inc., Kunshan (CN)

(21) Appl. No.: 19/299,255

(22) Filed: Aug. 13, 2025

(30) Foreign Application Priority Data
Aug. 15, 2024 (CN) 202411127822.6

(51) Int. Cl. H10K 59/122; H10K 59/123; H10K 59/35

(52) U.S. Cl. CPC H10K 59/122; H10K 59/123; H10K 59/352; H10K 59/353

(57) ABSTRACT

The present application discloses a display panel and a display device. The display panel includes: a substrate, including a base substrate, a third insulation layer formed with a communication hole, and a drive circuit located between the base substrate and the third insulation layer; a pixel defining layer disposed on one side of the substrate, the pixel defining layer including a pixel defining portion and a raised portion, the pixel defining portion and the raised portion jointly enclosing a pixel opening, and the raised portion protruding from the pixel defining portion toward the pixel opening; and a light-emitting device including a first electrode, the first electrode being partially exposed from the pixel opening, where the communication hole is located at least partially below the raised portion, and the first electrode is electrically connected to the drive circuit through the communication hole.

### CROSS-REFERENCE TO RELATED APPLICATIONS

The present application claims priority to the Chinese Patent Application No. 202411127822.6, filed on Aug. 15, 2024, and the entire contents of the aforementioned application are hereby incorporated by reference in its entirety.

### FIELD

The present application relates to the field of displays, and in particular to a display panel and a display device.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

However, the usage performance of conventional OLED display products needs to be improved.

### SUMMARY

Embodiments of the present application provide a display panel and a display device, with the aim of improving the display effect of the display panel.

An embodiment of a first aspect of the present application provides a display panel, including: a substrate, including a base substrate, a third insulation layer formed with a communication hole, and a drive circuit located between the base substrate and the third insulation layer; a pixel defining layer disposed on one side of the substrate, the pixel defining layer including at least one pixel defining portion and at least one raised portion connected to the at least one pixel defining portion, the pixel defining portion and the raised portion jointly enclosing at least one pixel opening, and the raised portion being located on a side of the pixel defining portion facing the pixel opening; and a light-emitting device including a first electrode, the first electrode being located on a side of the pixel defining layer facing the substrate and being at least partially exposed from the pixel opening, where the communication hole is located at least partially below the raised portion, and the first electrode is electrically connected to the drive circuit through the communication hole.

According to an implementation of the first aspect of the present application, the communication hole is located partially below the pixel defining portion.

According to any of the foregoing implementations of the first aspect of the present application, a first edge, a second edge, a third edge and a fourth edge are provided on the side of the pixel defining portion facing the pixel opening, where the first edge and the third edge are opposite in a first direction, the second edge and the fourth edge are opposite in a second direction, the raised portion is connected between the first edge and the second edge, and the first direction, the second direction and a thickness direction of the display panel intersect pairwise.

According to any of the foregoing implementations of the first aspect of the present application, the at least one pixel opening includes a plurality of pixel openings, the plurality of pixel openings are arranged at intervals in the first direction, and/or the plurality of pixel openings are arranged at intervals in the second direction.

According to any of the foregoing implementations of the first aspect of the present application, at least one orthographic projection of at least one of the first edge, the second edge, the third edge and the fourth edge on the substrate is linear.

According to any of the foregoing implementations of the first aspect of the present application, the first edge and the third edge extend in the second direction, and the second edge and the fourth edge extend in the first direction.

According to any of the foregoing implementations of the first aspect of the present application, the at least one pixel opening includes a first main opening portion and an extension opening portion which is located on a peripheral side of the first main opening portion and protrudes toward the pixel defining portion, the extension opening portion communicating with the first main opening portion, and the extension opening portion being located between the second edge, the third edge and the raised portion.

According to any of the foregoing implementations of the first aspect of the present application, a fifth edge and a sixth edge connected to each other are provided on a side of the raised portion facing the pixel opening, where the fifth edge is connected to the first edge, the sixth edge is connected to the second edge, and at least part of the fifth edge extends in a direction that intersects an extension direction of the second edge.

According to any of the foregoing implementations of the first aspect of the present application, at least part of the fifth edge extends in a direction that forms a minimum included angle of no more than 45° with the extension direction of the second edge.

According to any of the foregoing implementations of the first aspect of the present application, in a direction away from the first edge, the fifth edge is disposed obliquely toward the second edge.

According to any of the foregoing implementations of the first aspect of the present application, the fifth edge includes a first sub-edge and a second sub-edge connected to each other, where the first sub-edge is connected to the first edge, the second sub-edge is connected to the sixth edge, an orthographic projection of the first sub-edge on the substrate is arc-shaped, an orthographic projection of the second sub-edge on the substrate is linear, and the second sub-edge extends in a direction that intersects the extension direction of the second edge.

According to any of the foregoing implementations of the first aspect of the present application, the second sub-edge extends in a direction that forms a minimum included angle of no more than 45° with the extension direction of the second edge.

According to any of the foregoing implementations of the first aspect of the present application, the sixth edge includes a third sub-edge and a fourth sub-edge connected to each other, where the third sub-edge is connected to the fifth edge, the fourth sub-edge is connected to the second edge, an orthographic projection of the third sub-edge on the substrate is arc-shaped, and/or an orthographic projection of the fourth sub-edge on the substrate is arc-shaped, and the second sub-edge extends in a direction that intersects the extension direction of the second edge.

According to any of the foregoing implementations of the first aspect of the present application, the at least one pixel opening includes a first opening and a second opening, an area of the first opening is smaller than an area of the second opening, a dimension of the raised portion on a peripheral side of the first opening in a first direction is smaller than a dimension of the raised portion on a peripheral side of the second opening in the first direction, and/or a dimension of the raised portion on the peripheral side of the first opening in a second direction is smaller than a dimension of the raised portion on the peripheral side of the second opening in the second direction, and the first direction, the second direction and a thickness direction of the display panel intersect pairwise.

According to any of the foregoing implementations of the first aspect of the present application, the at least one pixel opening further includes a third opening, the area of the second opening is smaller than an area of the third opening, the dimension of the raised portion on the peripheral side of the second opening in the first direction is smaller than a dimension of the raised portion on a peripheral side of the third opening in the first direction, and/or the dimension of the raised portion on the peripheral side of the second opening in the second direction is smaller than a dimension of the raised portion on the peripheral side of the third opening in the second direction.

According to any of the foregoing implementations of the first aspect of the present application, the light-emitting device includes a first type of device arranged corresponding to the first opening, a second type of device arranged corresponding to the second opening, and a third type of device arranged corresponding to the third opening, where light-emitting colors of the first type of device, the second type of device and the third type of device are pairwise distinct.

According to any of the foregoing implementations of the first aspect of the present application, the light-emitting color of the first type of device is red, the light-emitting color of the second type of device is green, and the light-emitting color of the third type of device is blue.

According to any of the foregoing implementations of the first aspect of the present application, the display panel further includes an isolation structure disposed on a side of the pixel defining layer facing away from the substrate, the isolation structure enclosing at least one isolation opening in communication with the at least one pixel opening.

According to any of the foregoing implementations of the first aspect of the present application, the light-emitting device further includes a light-emitting unit disposed on a side of the first electrode facing away from the substrate and a second electrode disposed on a side of the light-emitting unit facing away from the substrate, a material of the isolation structure includes a conductive material, and the second electrode is connected to the isolation structure.

According to any of the foregoing implementations of the first aspect of the present application, the isolation structure includes a first isolation portion and a second isolation portion on a side of the first isolation portion facing away from the substrate, the second isolation portion protruding from the first isolation portion toward the isolation opening.

According to any of the foregoing implementations of the first aspect of the present application, the isolation structure further includes a conductive portion on a side of the first isolation portion facing the substrate, the conductive portion protruding from the first isolation portion toward the isolation opening, and the second electrode being connected to the conductive portion.

According to any of the foregoing implementations of the first aspect of the present application, the communication hole is located below the isolation opening.

According to any of the foregoing implementations of the first aspect of the present application, the isolation opening includes a second main opening portion and a clearance opening portion which is located on a peripheral side of the second main opening portion and protrudes toward the isolation structure, the clearance opening portion communicating with the main opening portion and being located above the raised portion, and the communication hole being located below the clearance opening portion.

According to any of the foregoing implementations of the first aspect of the present application, a projection of the communication hole in a thickness direction of the display panel is spaced apart from a projection of the isolation structure in the thickness direction of the display panel.

An embodiment of a first aspect of the present application further provides a display panel, including: a substrate; a pixel defining layer disposed on one side of the substrate, the pixel defining layer including a pixel defining portion, where the pixel defining portion encloses a pixel opening, and the pixel opening includes a first main opening portion and an extension opening portion which is located on a peripheral side of the first main opening portion and protrudes toward the pixel defining portion, the extension opening portion communicating with the first main opening portion; and a light-emitting device including a first electrode partially exposed from the pixel opening.

According to an implementation of the first aspect of the present application, the extension opening portion is located on a side of the first main opening portion in a second direction, the substrate located below the pixel defining layer on a side of the extension opening portion in a first direction is formed with a communication hole, part of the first electrode is located in the communication hole, and the first direction, the second direction and a thickness direction of the display panel intersect pairwise.

According to any of the foregoing implementations of the first aspect of the present application, a plurality of pixel openings are provided, the plurality of pixel openings are arranged at intervals in the first direction, and/or the plurality of pixel openings are arranged at intervals in the second direction.

According to any of the foregoing implementations of the first aspect of the present application, the pixel defining layer further includes a raised portion connected to an edge on a side of the pixel defining portion facing the pixel opening, the pixel defining portion and the raised portion jointly enclose the pixel opening, the raised portion protrudes from the pixel defining portion toward the pixel opening, and the extension opening portion is located on a peripheral side of the raised portion.

According to any of the foregoing implementations of the first aspect of the present application, the substrate includes a base substrate, a third insulation layer formed with a communication hole, and a drive circuit located between the base substrate and the third insulation layer, where the communication hole is located at least partially below the raised portion, and the first electrode is electrically connected to the drive circuit through the communication hole.

According to any of the foregoing implementations of the first aspect of the present application, the communication hole is located partially below the pixel defining portion.

According to any of the foregoing implementations of the first aspect of the present application, a first edge, a second edge, a third edge and a fourth edge are provided on the side of the pixel defining portion facing the pixel opening, where the first edge and the third edge are opposite in a first direction, the second edge and the fourth edge are opposite in a second direction, the raised portion is connected between the first edge and the second edge, and the first direction, the second direction and a thickness direction of the display panel intersect pairwise.

According to any of the foregoing implementations of the first aspect of the present application, at least one orthographic projection of at least one of the first edge, the second edge, the third edge and the fourth edge on the substrate is linear.

According to any of the foregoing implementations of the first aspect of the present application, the first edge and the third edge extend in the second direction, and the second edge and the fourth edge extend in the first direction.

According to any of the foregoing implementations of the first aspect of the present application, the extension opening portion is located between the second edge, the third edge and the raised portion.

According to any of the foregoing implementations of the first aspect of the present application, a fifth edge and a sixth edge connected to each other are provided on a side of the raised portion facing the pixel opening, where the fifth edge is connected to the first edge, the sixth edge is connected to the second edge, and at least part of the fifth edge extends in a direction that intersects an extension direction of the second edge.

According to any of the foregoing implementations of the first aspect of the present application, at least part of the fifth edge extends in a direction that forms a minimum included angle of no more than 45° with the extension direction of the second edge.

According to any of the foregoing implementations of the first aspect of the present application, in a direction away from the first edge, the fifth edge is disposed obliquely toward the second edge.

According to any of the foregoing implementations of the first aspect of the present application, the display panel further includes an isolation structure disposed on a side of the pixel defining layer facing away from the substrate, the isolation structure enclosing an isolation opening in communication with the pixel opening.

According to any of the foregoing implementations of the first aspect of the present application, the light-emitting device further includes a light-emitting unit disposed on a side of the first electrode facing away from the substrate and a second electrode disposed on a side of the light-emitting unit facing away from the substrate, a material of the isolation structure includes a conductive material, and the second electrode is connected to the isolation structure.

According to any of the foregoing implementations of the first aspect of the present application, the isolation structure includes a first isolation portion and a second isolation portion on a side of the first isolation portion facing away from the substrate, the second isolation portion protruding from the first isolation portion toward the isolation opening.

According to any of the foregoing implementations of the first aspect of the present application, the isolation structure further includes a conductive portion on a side of the first isolation portion facing the substrate, the conductive portion protruding from the first isolation portion toward the isolation opening, and the second electrode being connected to the conductive portion.

According to any of the foregoing implementations of the first aspect of the present application, the communication hole is located below the isolation opening.

According to any of the foregoing implementations of the first aspect of the present application, the isolation opening includes a second main opening portion and a clearance opening portion which is located on a peripheral side of the second main opening portion and protrudes toward the isolation structure, the clearance opening portion communicating with the main opening portion and being located on a peripheral side of the extension opening portion, and the communication hole being located below the clearance opening portion.

According to any of the foregoing implementations of the first aspect of the present application, a projection of the communication hole in a thickness direction of the display panel is spaced apart from a projection of the isolation structure in the thickness direction of the display panel.

An embodiment of a second aspect of the present application provides a display device, including a display panel of any of the above implementations.

In a display panel according to an embodiment of the present application, the display panel includes a substrate, a pixel defining layer and a light-emitting device. The pixel defining layer is disposed on one side of the substrate, the pixel defining layer includes a pixel defining portion and a raised portion, the pixel defining portion encloses a pixel opening, and the pixel defining layer may be configured to participate in partitioning sub-pixels of the display panel. The light-emitting device includes a first electrode, where the first electrode is partially exposed from the pixel opening, and the first electrode may serve as a pixel electrode of the display panel. The substrate includes a base substrate, a third insulation layer formed with a communication hole, and a drive circuit located between the base substrate and the third insulation layer, where the first electrode is electrically connected to the drive circuit through the communication hole, such that the first electrode may be electrically connected to the drive circuit through the communication hole.

The communication hole is provided at least partially below the raised portion, and the arrangement of the communication hole does not easily affect the flatness of the first electrode in the pixel opening. Moreover, the raised portion protrudes from the pixel defining portion toward the pixel opening, and the space occupied by the communication hole between adjacent pixel openings can be conveniently reduced, which allows for a smaller spacing between the adjacent pixel openings, thereby making it easy to increase the pixel density (Pixels Per Inch, PPI) of the display panel, and then better improving the display effect of the display panel.

### BRIEF DESCRIPTION OF THE DRAWINGS

In order to describe the embodiments of the present application more clearly, the drawings required for illustration of the embodiments of the present application will be briefly introduced below. The drawings as described below are only for some of the embodiments of the present application.

FIG. 1 is a partial sectional view of a display panel according to an embodiment of the present application;

FIG. 2 is a structural schematic diagram of a pixel defining layer according to an embodiment of the present application;

FIG. 3 is a schematic partial enlarged view of a pixel defining layer according to an embodiment of the present application;

FIG. 4 is a schematic partial enlarged view of a pixel defining layer according to a further embodiment of the present application;

FIG. 5 is a partial sectional view of a display panel according to a further embodiment of the present application;

FIG. 6 is a schematic partial enlarged view of a pixel defining layer and an isolation structure according to an embodiment of the present application;

FIG. 7 is a schematic partial enlarged view of an isolation structure according to an embodiment of the present application; and

FIG. 8 is a schematic partial enlarged view of a pixel defining layer according to a yet further embodiment of the present application.

### LIST OF REFERENCE SIGNS

10. Display panel;
100. Substrate; 100a. Communication hole; 110. Base substrate; 120. First insulation layer; 130. Second insulation layer; 140. Third insulation layer; 150. Drive circuit; 151. Transistor; 151a. Gate; 151b. Source and drain; 152. Storage capacitor; 152a. First plate; 152b. Second plate;
200. Pixel defining layer; 210. Pixel defining portion; 210a. Pixel opening; 210aa. First main opening portion; 210ab. Extension opening portion; 211. First edge; 212. Second edge; 213. Third edge; 214. Fourth edge; 220. Raised portion; 221. Fifth edge; 221a. First sub-edge; 221b. Second sub-edge; 222. Sixth edge; 222a. Third sub-edge; 222b. Fourth sub-edge;
300. Isolation structure; 300a. Isolation opening; 300aa. Second main opening portion; 300ab. Clearance opening portion; 310. First isolation portion; 320. Second isolation portion; 330. Conductive portion;
400. Light-emitting device; 410. First electrode; 420. Light-emitting unit; 430. Second electrode;
H1. First opening; H2. Second opening; H3. Third opening;
X. First direction;
Y. Second direction;
Z. Thickness direction.

### DETAILED DESCRIPTION OF THE EMBODIMENTS

Features and exemplary embodiments in various aspects of the present application will be described in detail below. In order to make the embodiments of the present application clearer, the present application will be further described in detail below with reference to the accompanying drawings and embodiments. It should be understood that the embodiments described herein are merely configured to explain the present application and are not configured to limit the present application. The present application may be implemented without some of these specific details. The following description of the embodiments is merely to provide a better understanding of the present application by illustrating examples of the present application.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, and a process, a method, an article, or a device that includes a list of elements not only includes those elements but also includes other elements that are not listed, or further includes elements inherent to such a process, method, article, or device. If no more limitations are made, an element limited by “comprising/including . . . ” does not exclude other identical elements existing in the process, the method, the article, or the device which includes the element.

It should be understood that in the description of the structure of a component, a layer or region referred as being located “above” or “over” another layer or region may be directly on the other layer or region, or there may be other layers or regions between the layer or region and the other layer or region. Moreover, if the component is turned over, the layer or region is located “below” or “under” the other layer or region.

Embodiments of the present application provide a display panel and a display device. Various embodiments of the display panel and the display device will be described below with reference to the drawings.

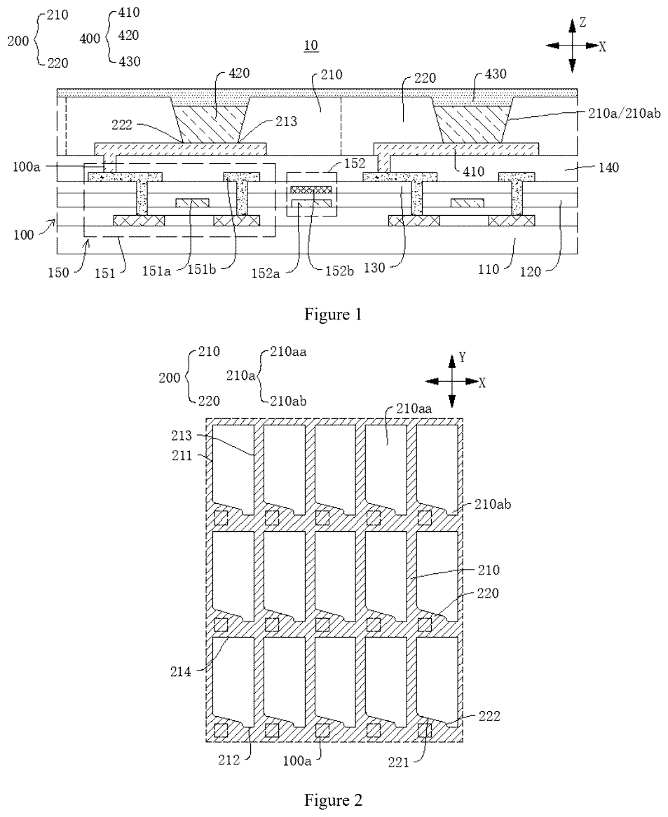

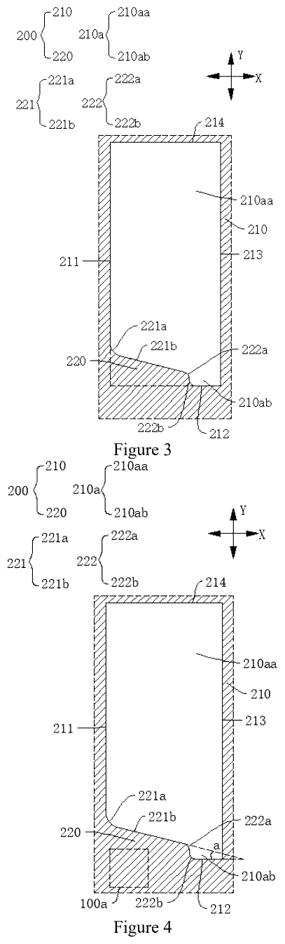

FIG. 1 is a partial sectional view of a display panel 10 according to an embodiment of the present application, FIG. 2 is a structural schematic diagram of a pixel defining layer 200 according to an embodiment of the present application, FIG. 3 is a schematic partial enlarged view of a pixel defining layer 200 according to an embodiment of the present application, and FIG. 4 is a schematic partial enlarged view of a pixel defining layer 200 according to a further embodiment of the present application. An X-direction in the figures can be a first direction, a Y-direction in the figures can be a second direction, and a Z-direction in the figures can be a thickness direction of the display panel 10. Every two of the first direction X, the second direction Y and the thickness direction Z of the display panel 10 may intersect with each other. For example, every two of the first direction X, the second direction Y and the thickness direction Z of the display panel 10 may be perpendicular to each other. Illustratively, some dashed box areas in FIGS. 2 and 4 illustrate the placement of communication holes 100a below the pixel defining layer 200.

As shown in FIGS. 1 to 4, an embodiment of a first aspect of the present application provides a display panel 10, including: a substrate 100, including a base substrate 110, a third insulation layer 140 formed with a communication hole 100a, and a drive circuit 150 located between the base substrate 110 and the third insulation layer 140; a pixel defining layer 200 disposed on one side of the substrate 100, the pixel defining layer 200 including at least one pixel defining portion 210 and at least one raised portion 220 connected to the at least one pixel defining portion 210, the pixel defining portion 210 and the raised portion 220 jointly enclosing at least one pixel opening 210a, and the raised portion 220 being located on a side of the pixel defining portion 210 facing the pixel opening 210a; and a light-emitting device 400 including a first electrode 410, the first electrode 410 being located on a side of the pixel defining layer 200 facing the substrate 100 and being at least partially exposed from the pixel opening 210a, where the communication hole 100a is located at least partially below the raised portion 220, and the first electrode 410 is electrically connected to the drive circuit 150 through the communication hole 100a.

In a display panel 10 according to an embodiment of the present application, the display panel 10 includes a substrate 100, a pixel defining layer 200 and a light-emitting device 400. The pixel defining layer 200 is disposed on one side of the substrate 100, the pixel defining layer 200 includes a pixel defining portion 210 and a raised portion 220, the pixel defining portion 210 encloses a pixel opening 210a, and the pixel defining layer 200 may be configured to participate in partitioning sub-pixels of the display panel 10. The light-emitting device 400 includes a first electrode 410, where the first electrode 410 is partially exposed from the pixel opening 210a, and the first electrode 410 may serve as a pixel electrode of the display panel 10. The substrate 100 includes a base substrate 110, a third insulation layer 140 formed with a communication hole 100a, and a drive circuit 150 located between the base substrate 110 and the third insulation layer 140, where the first electrode 410 is electrically connected to the drive circuit 150 through the communication hole 100a, such that the first electrode 410 may be electrically connected to the drive circuit 150 through the communication hole 100a.

In one embodiment, a plurality of pixel openings 210a and a plurality of light-emitting devices 400 may be provided, and the light-emitting devices 400 can be arranged corresponding to different pixel openings 210a, i.e., the light-emitting devices 400 may be located in different pixel openings 210a.

The raised portion 220 may be connected to an edge of a side of the pixel defining portion 210 facing the pixel opening 210a. The communication hole 100a is provided at least partially below the raised portion 220, and the arrangement of the communication hole 100a does not easily affect the flatness of the first electrode 410 in the pixel opening 210a. Moreover, the raised portion 220 protrudes from the pixel defining portion 210 toward the pixel opening 210a, and the space occupied by the communication hole 100a between adjacent pixel openings 210a can be conveniently reduced, which allows for a smaller spacing between the adjacent pixel openings 210a, thereby making it easy to increase the pixel density of the display panel 10, and then better improving the display effect of the display panel 10.

In some embodiments of the present application, there are a number of ways in which the substrate 100 is arranged. In one embodiment, in a direction away from the base substrate 110, the substrate 100 may include a first insulation layer 120, a second insulation layer 130 and a third insulation layer 140 which are sequentially stacked. Illustratively, the drive circuit 150 may include a transistor 151, a storage capacitor 152, and drive signal lines for connecting various devices, etc. The transistor 151 includes a semiconductor, a gate 151a, and a source and drain 151b. The storage capacitor 152 includes a first plate 152a and a second plate 152b.

As an example, the gate 151a and the first plate 152a may be located on a side of the first insulation layer 120 facing the base substrate 110, the second plate 152b may be located between the first insulation layer 120 and the second insulation layer 130, and the source and drain 151b may be located between the second insulation layer 130 and the third insulation layer 140.

In one embodiment, the third insulation layer 140 may act as a planarization layer of the display panel 10.

In one embodiment, the communication hole 100a may be provided through the third insulation layer 140, and the first electrode 410 may be connected to the transistor 151 in the substrate 100 through the communication hole 100a to transfer a drive current, for example, the first electrode 410 may be connected to the source and drain 151b of the transistor 151 in the substrate 100 through the communication hole 100a.

In some optional embodiments, the light-emitting device 400 may also include a light-emitting unit 420 disposed on a side of the first electrode 410 facing away from the substrate 100 and a second electrode 430 disposed on a side of the light-emitting unit 420 facing away from the substrate 100.

In one embodiment, the light-emitting unit 420 may include a hole injection layer (Hole Inject Layer, HIL), a hole transport layer (Hole Transport Layer, HTL), a light-emitting structure, an electron injection layer (Electron Inject Layer, EIL) and an electron transport layer (Electron Transport Layer, ETL).

In these optional embodiments, the first electrode 410 and the second electrode 430 may act as pixel electrodes of the display panel 10, and one of the first electrode 410 and the second electrode 430 may act as an anode and the other may act as a cathode to drive the light-emitting unit 420 to emit light. An embodiment of the present application is exemplified by using the first electrode 410 as the anode of the display panel 10 and the second electrode 430 as the cathode of the display panel 10.

In some embodiments of the present application, the first electrode 410 is partially exposed from the pixel opening 210a, which may mean that the first electrode 410 may be partially covered by the pixel defining portion 210 and the raised portion 220, and the pixel opening 210a enclosed by the pixel defining portion 210 and the raised portion 220 may be located above the first electrode 410.

In one embodiment, a portion of a surface on a side of the single first electrode 410 facing away from the substrate 100 may be covered by the pixel defining portion 210 and the raised portion 220, and the other portion of the surface on the side of the first electrode 410 facing away from the substrate 100 may not be covered by the pixel defining portion 210 and the raised portion 220 and may be exposed from the pixel opening 210a, such that a surface of the first electrode 410 that is not covered by the pixel defining portion 210 and the raised portion 220 and exposed from the pixel opening 210a may be brought into contact with the light-emitting unit 420, facilitating light emission of the light-emitting unit 420 driven by the first electrode 410.

In some embodiments of the present application, the communication hole 100a is located at least partially below the raised portion 220, which may mean that a projection of the communication hole 100a in the thickness direction Z of the display panel 10 at least partially overlaps a projection of the raised portion 220 in the thickness direction Z of the display panel 10. For example, an orthographic projection of the communication hole 100a on the base substrate 110 at least partially overlaps an orthographic projection of the raised portion 220 on the base substrate 110.

In one embodiment, depending on the shape of the communication hole 100a, the raised portion 220 may also partially fall into the communication hole 100a.

In some optional embodiments, the communication hole 100a may be located partially below the pixel defining portion 210, i.e., part of the communication hole 100a may be located below the pixel defining portion 210 and the other part below the raised portion 220.

In one embodiment, the communication hole 100a may be partially located below the pixel defining portion 210, which may mean that the projection of the communication hole 100a in the thickness direction Z of the display panel 10 partially overlaps a projection of the pixel defining portion 210 in the thickness direction Z of the display panel 10. For example, the orthographic projection of the communication hole 100a on the base substrate 110 partially overlaps an orthographic projection of the pixel defining portion 210 on the base substrate 110.

In one embodiment, depending on the shape of the communication hole 100a, the pixel defining portion 210 may also partially fall into the communication hole 100a.

In these optional embodiments, by providing the communication hole 100a partially below the pixel defining portion 210, the first electrode 410 at the communication hole 100a may be covered by the pixel defining portion 210 and the raised portion 220, and the provided raised portion 220 may have a smaller size, to reduce the effect of the blocking of the raised portion 220 on the first electrode 410 in the pixel opening 210a, and the first electrode 410 in the pixel opening 210a can have a larger contact area with the light-emitting unit 420, to improve the light-emitting display effect of the display panel 10.

In some embodiments of the present application, the raised portion 220 is arranged in various ways at an edge on the side of the pixel defining portion 210 facing the pixel opening 210a.

In some optional embodiments, a first edge 211, a second edge 212, a third edge 213 and a fourth edge 214 are provided on the side of the pixel defining portion 210 facing the pixel opening 210a, where the first edge 211 and the third edge 213 are opposite in the first direction X, the second edge 212 and the fourth edge 214 are opposite in the second direction Y, and the raised portion 220 is connected between the first edge 211 and the second edge 212.

In one embodiment, the first edge 211, the second edge 212, the third edge 213 and the fourth edge 214 may be edges on the side of the pixel defining portion 210 facing the pixel opening 210a and in contact with the first electrode 410.

In one embodiment, a first edge 211, a second edge 212, a third edge 213 and a fourth edge 214 are provided on the side of the pixel defining portion 210 facing the pixel opening 210a, which may specifically mean that the first edge 211, the second edge 212, the third edge 213 and the fourth edge 214 are provided on a side of a surface on a side of the pixel defining portion 210 facing the first electrode 410 that faces the pixel opening 210a.

In one embodiment, the raised portion 220 is connected between the first edge 211 and the second edge 212, which may mean that the raised portion 220 may be disposed at an end on a side of the first edge 211 away from the fourth edge 214, and the raised portion 220 may be disposed at an end on a side of the second edge 212 away from the third edge 213.

In one embodiment, at least one of the first edge 211, the second edge 212, the third edge 213 and the fourth edge 214 has a linear orthographic projection shape on the substrate 100.

In one embodiment, the first edge 211 and the third edge 213 extend in the second direction Y, and the second edge 212 and the fourth edge 214 extend in the first direction X.

In one embodiment, a dimension of the first edge 211 in the second direction Y is less than a dimension of the third edge 213 in the second direction Y, and a dimension of the second edge 212 in the first direction X is less than a dimension of the fourth edge 214 in the first direction X.

In one embodiment, a plurality of pixel openings 210a are provided, the plurality of pixel openings 210a are arranged at intervals in the first direction X, and/or the plurality of pixel openings 210a are arranged at intervals in the second direction Y.

In these optional embodiments, the raised portion 220 is connected between the first edge 211 and the second edge 212, i.e., the raised portion 220 is disposed at a corner between the first edge 211 and the second edge 212, such that the connection hole below the raised portion 220 does not easily occupy a space between the third edge 213 and an adjacent pixel opening 210a or a space between the fourth edge 214 and an adjacent pixel opening 210a, and a smaller spacing may be provided between the third edge 213 and the adjacent pixel opening 210a and between the fourth edge 214 and the adjacent pixel opening 210a, thereby increasing the pixel density of the display panel 10, and then better improving the display effect of the display panel 10.

Moreover, since the raised portion 220 protrudes from the pixel defining portion 210 toward the pixel opening 210a, the first edge 211 may have a certain segment difference from the raised portion 220 in the first direction X, and the second edge 212 may have a segment difference from the raised portion 220 in the second direction Y, the first edge 211 may have a smaller spacing from the adjacent pixel opening 210a in the first direction X, and the second edge 212 may have a smaller spacing from the adjacent pixel opening 210a in the second direction Y, thereby increasing the pixel density of the display panel 10, and then better improving the display effect of the display panel 10.

In one embodiment, the spacing between adjacent pixel openings 210a can be 4 microns to 8 microns.

In some optional embodiments, the pixel opening 210a includes a first main opening portion 210aa and an extension opening portion 210ab which is located on a peripheral side of the first main opening portion 210aa and protrudes toward the pixel defining portion 210, the extension opening portion 210ab communicating with the first main opening portion 210aa.

In one embodiment, an extension opening may be located on a peripheral side of the raised portion 220. In one embodiment, the extension opening portion 210ab may be located between the second edge 212, the third edge 213 and the raised portion 220.

In one embodiment, the extension opening portion 210ab is located on a side of the first main opening portion 210aa in the second direction Y, and the substrate 100 located below the pixel defining layer 200 on a side of the extension opening portion 210ab in the first direction X is formed with a communication hole 100a, part of the first electrode 410 being located in the communication hole 100a.

For example, the extension opening portion 210ab is located on a side of the first main opening portion 210aa close to the second edge 212 in the second direction Y, and the substrate 100 located below the raised portion 220 on a side of the extension opening portion 210ab close to the first edge 211 in the first direction X is formed with a communication hole 100a, part of the first electrode 410 being located in the communication hole 100a.

In these optional embodiments, the extension opening portion 210ab is configured to protrude toward the pixel defining portion 210 on the peripheral side of the first main opening portion 210aa, and the pixel opening 210a may have a larger area to increase a contact area between the first electrode 410 and the light-emitting unit 420, the second edge 212 enclosing the peripheral side of the extension opening portion 210ab is also possible to be closer to the adjacent pixel opening 210a in the second direction Y, and the second edge 212 may have a smaller spacing from the adjacent pixel opening 210a in the second direction Y, thereby increasing the pixel density of the display panel 10, and then better improving the display effect of the display panel 10.

In some optional embodiments, a fifth edge 221 and a sixth edge 222 connected to each other are provided on a side of the raised portion 220 facing the pixel opening 210a, the fifth edge 221 is connected to the first edge 211, the sixth edge 222 is connected to the second edge 212, and at least part of the fifth edge 221 extends in a direction that intersects an extension direction of the second edge 212.

In one embodiment, the fifth edge 221 and the sixth edge 222 may be edges on the side of the raised portion 220 facing the pixel opening 210a and in contact with the first electrode 410.

In one embodiment, the fifth edge 221 and the sixth edge 222 are provided on the side of the raised portion 220 facing the pixel opening 210a, which may specifically mean that the fifth edge 221 and the sixth edge 222 are provided on a side of a surface on a side of the raised portion 220 facing the first electrode 410 that faces the pixel opening 210a.

In one embodiment, the extension opening portion 210ab may be located between the second edge 212, the third edge 213 and the sixth edge 222.

In one embodiment, at least part of the fifth edge 221 extends in a direction that intersects the extension direction of the second edge 212, which may mean that at least part of the fifth edge 221 extends in a direction that intersects the first direction X. In one embodiment, an extension direction of a portion of the fifth edge 221 having a linear orthographic projection shape on the substrate 100 may intersect the first direction X. Illustratively, the extension direction of the portion of the fifth edge 221 having the linear orthographic projection shape on the substrate 100 may also intersect the second direction Y and the thickness direction Z of the display panel 10.

In one embodiment, at least part of the fifth edge 221 extends in a direction that forms a minimum included angle of no more than 45° with an extension direction of the second edge 212.

In one embodiment, an angle a in FIG. 4 may illustrate the minimum included angle between an extension direction of at least part of the fifth edge 221 and the extension direction of the second edge 212. In one embodiment, the minimum included angle between the extension direction of at least part of the fifth edge 221 and the extension direction of the second edge 212 may be 45°, 40°, 35°, 30°, 25°, or 20°, etc.

In one embodiment, in a direction away from the first edge 211, the fifth edge 221 is disposed obliquely toward the second edge 212.

In these optional embodiments, at least part of the fifth edge 221 extends in a direction that intersects the extension direction of the second edge 212, so it is possible to facilitate adjusting the degree of protrusion of the raised portion 220 with respect to the pixel defining portion 210, such that the arrangement of the raised portion 220 is not easy to occupy an area of the pixel opening 210a that is too large, thereby increasing a light-emitting area of sub-pixels of the display panel 10. Moreover, in a direction away from the first edge 211, the fifth edge 221 is disposed obliquely toward the second edge 212, and the end of the fifth edge 221 connected to the first edge 211 is enabled to be closer to the fourth edge 214, and the end of the fifth edge 221 connected to the second edge 212 can be farther away from the fourth edge 214, such that the position on the raised portion 220 closer to the first edge 211 has a larger dimension in the second direction Y, thus it is possible to facilitate arranging the communication hole 100a below the raised portion 220 near the first edge 211, in addition, the raised portion 220 does not easily occupy an area of the pixel opening 210a that is too large at a position near the second edge 212, thereby increasing the light-emitting area of the sub-pixels of the display panel 10.

In some optional embodiments, the fifth edge 221 includes a first sub-edge 221a and a second sub-edge 221b connected to each other, where the first sub-edge 221a is connected to the first edge 211, the second sub-edge 221b is connected to the sixth edge 222, an orthographic projection of the first sub-edge 221a on the substrate 100 is arc-shaped, an orthographic projection of the second sub-edge 221b on the substrate 100 is linear, and the second sub-edge 221b extends in a direction that intersects the extension direction of the second edge 212.

In one embodiment, a radius of the orthographic projection of the first sub-edge 221a and/or the second sub-edge 221b on the substrate 100 may be 0.5 microns to 2 microns.

In one embodiment, the minimum included angle between the extension direction of the second sub-edge 221b and the extension direction of the second edge 212 is no more than 45°.

In these optional embodiments, the expression “at least part of the fifth edge 221 extends in a direction that intersects the extension direction of the second edge 212” as described above may specifically mean that “the second sub-edge 221b of the fifth edge 221 extends in a direction that intersects the extension direction of the second edge 212”. The first sub-edge 221a with an arc-shaped orthographic projection shape on the substrate 100 is provided between the second sub-edge 221b and the first edge 211, so it is possible to adjust the area of the raised portion 220 such that the fifth edge 221 may have a good spacing from the communication hole 100a, thus better reducing the effect of the communication hole 100a on the flatness of the fifth edge 221 in the thickness direction Z of the display panel 10. Moreover, the first sub-edge 221a with an arc-shaped orthographic projection on the substrate 100 is also easily prepared, thus reducing the difficulty of preparing the pixel defining layer 200.

In some optional embodiments, the sixth edge 222 includes a third sub-edge 222a and a fourth sub-edge 222b connected to each other, where the third sub-edge 222a is connected to the fifth edge 221, the fourth sub-edge 222b is connected to the second edge 212, the third sub-edge 222a has an arc-shaped orthographic projection on the substrate 100, and/or the fourth sub-edge 222b has an arc-shaped orthographic projection on the substrate 100, and the second sub-edge 221b extends in a direction that intersects the extension direction of the second edge 212.

In this optional embodiment, an orthographic projection of the third sub-edge 222a on the substrate 100 is arc-shaped, and an orthographic projection of the fourth sub-edge 222b on the substrate 100 is arc-shaped, so it is possible to adjust the area of the raised portion 220 such that the sixth edge 222 may have a good spacing from the communication hole 100a, thus better reducing the effect of the communication hole 100a on the flatness of the sixth edge 222 in the thickness direction Z of the display panel 10. Moreover, the third sub-edge 222a and the fourth sub-edge 222b each having an arc-shaped orthographic projection on the substrate 100 are also easily prepared, thus reducing the difficulty of preparing the pixel defining layer 200.

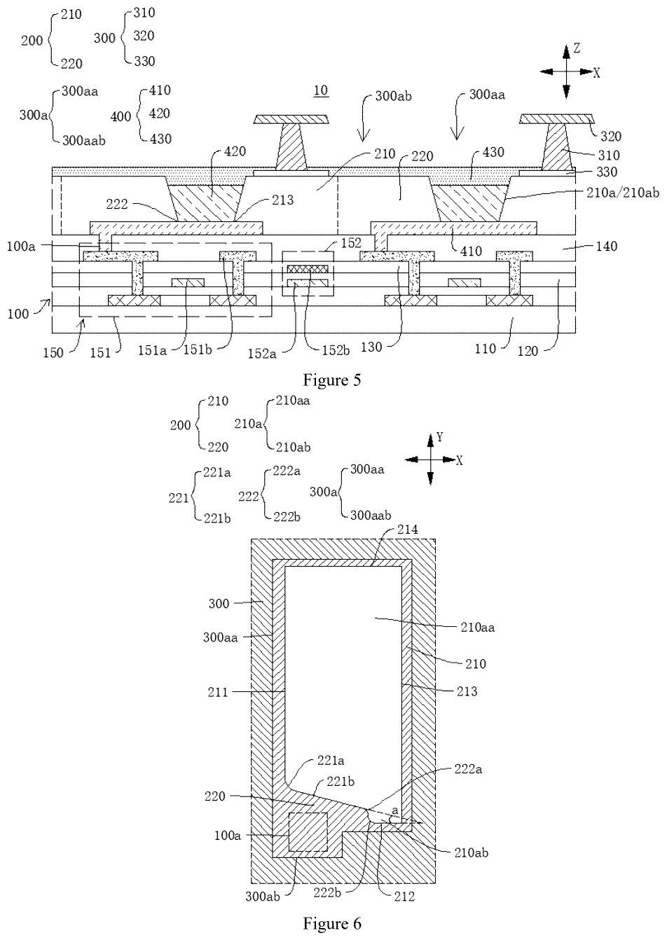

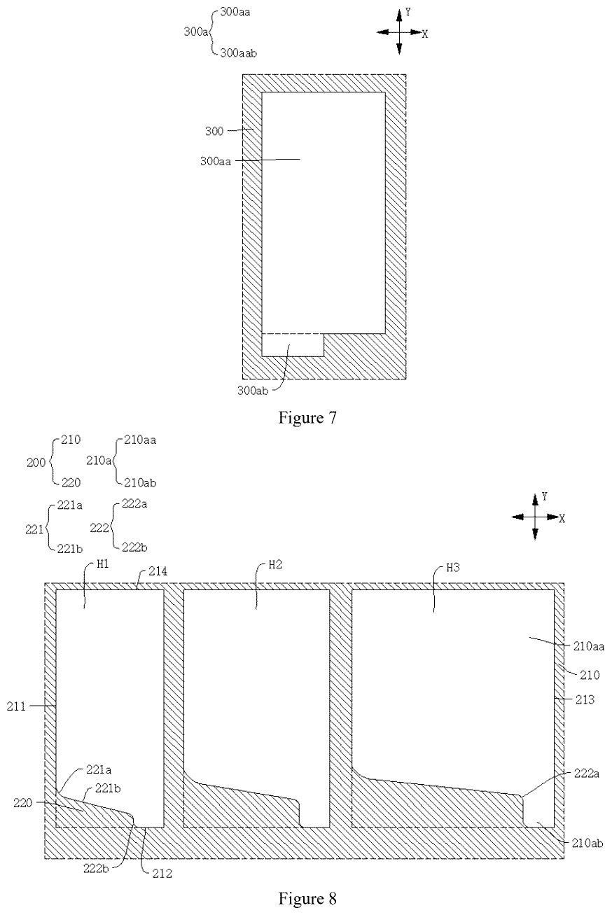

FIG. 5 is a partial sectional view of a display panel 10 according to a further embodiment of the present application, FIG. 6 is a schematic partial enlarged view of a pixel defining layer 200 and an isolation structure 300 according to an embodiment of the present application, and FIG. 7 is a schematic partial enlarged view of an isolation structure 300 according to an embodiment of the present application.

As shown in FIGS. 4 to 7, in some optional embodiments, the display panel 10 further includes an isolation structure 300 disposed on a side of the pixel defining layer 200 facing away from the substrate 100, where the isolation structure 300 encloses at least one isolation opening 300a in communication with the at least one pixel opening 210a, and the isolation structure 300 may also be configured to participate in partitioning sub-pixels of the display panel 10.

In one embodiment, the isolation structure 300 may include a first isolation portion 310 and a second isolation portion 320 on a side of the first isolation portion 310 facing away from the substrate 100, the second isolation portion 320 protruding from the first isolation portion 310 toward the isolation opening 300a.

The second isolation portion 320 protrudes from the first isolation portion 310 toward the isolation opening 300a, such that when the light-emitting unit 420 and the second electrode 430 of the display panel 10 are evaporated, the second isolation portion 320 is capable of shielding at least part of a material configured to prepare the light-emitting unit 420 and the second electrode 430, to separate the material of the light-emitting unit 420 and the second electrode 430 between adjacent sub-pixels, and to facilitate forming a plurality of light-emitting units 420 and second electrodes 430 which are arranged at intervals, and it is not necessary to provide a mask with high precision when the light-emitting unit 420 and the second electrode 430 of the display panel 10 are evaporated. For example, this eliminates the need to provide a high-precision metal mask (Fine Metal Mask, FMM) when the light-emitting unit 420 and the second electrode 430 are evaporated, which can better reduce the production and manufacturing costs of the display panel 10.

In one embodiment, the material of the isolation structure 300 may include a conductive material, and the second electrode 430 may be connected to the isolation structure 300. For example, the second electrode 430 may be connected to the first isolation portion 310 such that the second electrodes 430 in the adjacent isolation openings 300a may be electrically connected by the isolation structure 300, i.e., the second electrodes 430 in the adjacent isolation openings 300a may be interconnected by the isolation structure 300 to form a continuous electrode, thereby facilitating control over the second electrodes 430 in the display panel 10.

In one embodiment, the isolation structure 300 further includes a conductive portion 330 on a side of the first isolation portion 310 facing the substrate 100, and the conductive portion 330 may protrude from the first isolation portion 310 toward the isolation opening 300a. The second electrode 430 may be connected to the conductive portion 330, and the conductive portion 330 may protrude from the first isolation portion 310 toward the isolation opening 300a, which can facilitate overlapping between the second electrode 430 and the conductive portion 330, and can better increase an overlapping area between the second electrode 430 and the conductive portion 330 to reduce the resistance of the display panel 10.

In some optional embodiments, the communication hole 100a may be located below the isolation opening 300a.

In one embodiment, the communication hole 100a is located below the isolation opening 300a, which may mean that the orthographic projection of the communication hole 100a on the base substrate 110 may at least partially overlap the orthographic projection of the isolation opening 300a on the base substrate 110, for example, the orthographic projection of the communication hole 100a on the base substrate 110 may be located within the orthographic projection of the isolation opening 300a on the base substrate 110.

In one embodiment, the isolation opening 300a includes a second main opening portion 300aa and a clearance opening portion 300ab which is located at a peripheral side of the second main opening portion 300aa and protrudes toward the isolation structure 300, where the clearance opening portion 300ab communicates with the main opening portion, and the communication hole 100a is located below the clearance opening portion 300ab.

In one embodiment, the communication hole 100a is located below the clearance opening portion 300ab, which may mean that the orthographic projection of the communication hole 100a on the base substrate 110 may at least partially overlap the orthographic projection of the clearance opening portion 300ab on the base substrate 110, for example, the orthographic projection of the communication hole 100a on the base substrate 110 may be located within the orthographic projection of the clearance opening portion 300ab on the base substrate 110.

In one embodiment, the clearance opening portion 300ab is located on a peripheral side of the extension opening portion 210ab. In one embodiment, the clearance opening portion 300ab is located above the raised portion 220.

In one embodiment, the clearance opening portion 300ab is located above the raised portion 220, which may mean that the orthographic projection of the clearance opening portion 300ab on the base substrate 110 may at least partially overlap the orthographic projection of the raised portion 220 on the base substrate 110, for example, the orthographic projection of the raised portion 220 on the base substrate 110 may be located within the orthographic projection of the clearance opening portion 300ab on the base substrate 110.

In one embodiment, the projection of the communication hole 100a in the thickness direction Z of the display panel 10 is spaced apart from a projection of the isolation structure 300 in the thickness direction Z of the display panel 10. For example, the orthographic projection of the communication hole 100a on the base substrate 110 is spaced apart from an orthographic projection of the isolation structure 300 on the base substrate 110.

In these optional embodiments, the communication hole 100a is provided below the isolation opening 300a, for example, the communication hole 100a is provided below the clearance opening portion 300ab, and the communication hole 100a can be better staggered from the isolation structure 300, that is, it is possible to not arrange the communication hole 100a below the isolation structure 300, to better reduce the effect of the arrangement of the communication hole 100a on the flatness of the isolation structure 300, enabling respective film structures in the isolation structure 300 to have better flatness in the thickness direction Z of the display panel 10, enhancing the structural stability of the isolation structure 300, facilitating the overlapping of the second electrode 430 with the isolation structure 300, and improving the overlapping reliability of the second electrode 430 with the isolation structure 300.

FIG. 8 is a schematic partial enlarged view of a pixel defining layer 200 according to a yet further embodiment of the present application.

As shown in FIG. 8, in some optional embodiments, the pixel opening 210a may include a first opening H1 and a second opening H2.

In one embodiment, the pixel opening 210a may also include a third opening H3.

In these optional embodiments, the first opening H1, the second opening H2 and the third opening H3 may be configured to accommodate light-emitting devices 400 of different light-emitting colors, respectively. For example, the light-emitting device 400 includes a first type of device arranged corresponding to the first opening H1, a second type of device arranged corresponding to the second opening H2, and a third type of device arranged corresponding to the third opening H3, where light-emitting colors of the first type of device, the second type of device and the third type of device are pairwise distinct.

Illustratively, the light-emitting color of the first type of device is red, the light-emitting color of the second type of device is green, and the light-emitting color of the third type of device is blue, that is, the first opening H1 may be configured to accommodate the light-emitting device 400 capable of emitting red light, the second opening H2 may be configured to accommodate the light-emitting device 400 capable of emitting green light, and the third opening H3 may be configured to accommodate the light-emitting device 400 capable of emitting blue light.

In some embodiments of the present application, the sizes of the light-emitting devices 400 of different light-emitting colors are different due to the need to consider a color ratio of a light-emitting material system, and the sizes of the pixel openings 210a for accommodating the light-emitting devices 400 of different light-emitting colors are also different.

In one embodiment, the area of the first opening H1 may be smaller than the area of the second opening H2. In one embodiment, the area of the second opening H2 is smaller than the area of the third opening H3.

In one embodiment, the area of the pixel opening 210a may refer to an area of an orthographic projection of the pixel opening 210a on the substrate 100. For example, the area of the first opening H1 may refer to an area of an orthographic projection of the first opening H1 on the substrate 100.

In some optional embodiments, when the area of the first opening H1 may be smaller than the area of the second opening H2, the dimension of the raised portion 220 on a peripheral side of the first opening H1 in the first direction X is smaller than the dimension of the raised portion 220 on a peripheral side of the second opening H2 in the first direction X, and/or the dimension of the raised portion 220 on the peripheral side of the first opening H1 in the second direction Y is smaller than the dimension of the raised portion 220 on the peripheral side of the second opening H2 in the second direction Y.

In one embodiment, the raised portion 220 on the peripheral side of the first opening H1 may refer to the raised portion 220 that participates in enclosing the first opening H1. In one embodiment, the raised portion 220 on the peripheral side of the second opening H2 may refer to the raised portion 220 that participates in enclosing the second opening H2.

In one embodiment, when the area of the second opening H2 is smaller than the area of the third opening H3, the dimension of the raised portion 220 on the peripheral side of the second opening H2 in the first direction X is smaller than the dimension of the raised portion 220 on a peripheral side of the third opening H3 in the first direction X, and/or the dimension of the raised portion 220 on the peripheral side of the second opening H2 in the second direction Y is smaller than the dimension of the raised portion 220 on the peripheral side of the third opening H3 in the second direction Y.

In one embodiment, the raised portion 220 on the peripheral side of the third opening H3 may refer to the raised portion 220 that participates in enclosing the third opening H3.

In these optional embodiments, raised portions 220 of different sizes are arranged according to the sizes of different pixel openings 210a, and the flexibility in the arrangement of the communication holes 100a on peripheral sides of pixel openings 210a of different sizes may be rationally adjusted. In particular, a raised portion 220 having a smaller size is provided on the peripheral side of the first opening H1 having a smaller size, and the raised portion 220 on the peripheral side of the first opening H1 is not easy to compress the size of the first opening H1 too much, thereby better improving the display effect of the light-emitting device 400 in the first opening H1. Moreover, a raised portion 220 having a larger size is provided on each of the peripheral side of the second opening H2 having a larger size and the peripheral side of the third opening H3 having a larger size, and it is easy to dispose the communication holes 100a below the raised portions 220 on the peripheral sides of the second opening H2 and the third opening H3, which can better reduce the difficulty in preparing the display panel 10.

As shown in FIGS. 1 to 8, an embodiment of the first aspect of the present application further provides a display panel 10, including: a substrate 100; a pixel defining layer 200 disposed on one side of the substrate 100, the pixel defining layer 200 including a pixel defining portion 210, where the pixel defining portion 210 encloses a pixel opening 210a, and the pixel opening 210a includes a first main opening portion 210aa and an extension opening portion 210ab which is located on a peripheral side of the first main opening portion 210aa and protrudes toward the pixel defining portion 210, the extension opening portion 210ab communicating with the first main opening portion 210aa; and a light-emitting device 400 including a first electrode 410, where the first electrode 410 is partially exposed from the pixel opening 210a.

In a display panel 10 according to an embodiment of the present application, the display panel 10 includes a substrate 100, a pixel defining layer 200 and a light-emitting device 400. The pixel defining layer 200 is disposed on one side of the substrate 100, the pixel defining layer 200 includes a pixel defining portion 210, the pixel defining portion 210 encloses a pixel opening 210a, and the pixel defining layer 200 may be configured to participate in partitioning sub-pixels of the display panel 10. The light-emitting device 400 includes a first electrode 410, where the first electrode 410 is partially exposed from the pixel opening 210a, and the first electrode 410 may serve as a pixel electrode of the display panel 10.

The pixel opening 210a includes a first main opening portion 210aa and an extension opening portion 210ab which is located on a peripheral side of the first main opening portion 210aa and communicates with the first main opening portion 210aa, and the extension opening portion 210ab protrudes toward the pixel defining portion 210, and it is possible for the pixel opening 210a to have a large area to increase a light-emitting area of the sub-pixels of the display panel 10, and it is also possible to enable the extension opening portion 210ab to be closer to the adjacent pixel opening 210a such that a smaller spacing from the adjacent pixel opening 210a can be achieved, which makes it easy to increase the pixel density of the display panel 10, and then better improves the display effect of the display panel 10.

In one embodiment, an embodiment of the first aspect of the present application further provides a display panel 10 that may be the display panel 10 of any of the foregoing embodiments, so an embodiment of the present application further provides a display panel 10 that may have the structure and beneficial effects of the display panel 10 in any of the embodiments described above, which is not described in detail herein.

For example, the light-emitting device 400 may be the light-emitting device 400 in any of the foregoing embodiments, and the light-emitting device 400 may also include the light-emitting unit 420 and the second electrode 430 in any of the foregoing embodiments. Illustratively, the first electrode 410 and the second electrode 430 may serve as an anode and a cathode of the display panel 10, respectively. For example, the substrate 100 may be the substrate 100 in any of the foregoing embodiments, and the substrate 100 may be formed with communication holes 100a in any of the foregoing embodiments. The communication hole 100a may be formed in the third insulation layer 140, and the first electrode 410 may be connected to the source and drain 151b of the transistor 151 in the substrate 100 through the communication hole 100a, and the transistor 151 may supply a current to the first electrode 410 to drive the light-emitting unit 420 for light emission and display. For example, the pixel defining layer 200 may be the pixel defining layer 200 in any of the foregoing embodiments, the pixel defining layer 200 may include the pixel defining portion 210 and the raised portion 220 in any of the foregoing embodiments, the pixel opening 210a may be enclosed by the pixel defining portion 210 and the raised portion 220, and the pixel opening 210a may include a first main opening portion 210aa and an extension opening portion 210ab in any of the foregoing embodiments.

In one embodiment, the display panel 10 may further include an isolation structure 300 in any of the foregoing embodiments, for example, the isolation structure 300 may enclose an isolation opening 300a in any of the foregoing embodiments, the isolation opening 300a may include a second main opening portion 300aa and a clearance opening portion 300ab in any of the foregoing embodiments, and the isolation structure 300 may include a first isolation portion 310, a second isolation portion 320 and a conductive portion 330 in any of the foregoing embodiments. The relative positional relationship of the communication hole 100a and the isolation structure 300 may also be set with reference to the foregoing embodiments.

With regard to the isolation structure (also becoming a partition structure, etc.), patents (applications) PCT/CN2023/134518, 202310759370.2, 202310740412.8, 202310707209.0, and 202311346196.5 describe related structural compositions, manufacturing methods, etc., the contents of which are incorporated herein by reference.

An embodiment of a second aspect of the present application provides a display device, including a display panel 10 of any of the above implementations. Since the display device according to the embodiment of the second aspect of the present application includes the display panel 10 of any one of the above embodiments of the first aspect, the display device according to the embodiment of the second aspect of the present application has the beneficial effects of the display panel 10 of any one of the above embodiments of the first aspect, and will not be described in detail here.

The display device in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present disclosure to only the described specific embodiments. Apparently, many modifications and variations can be made in light of the above description. The embodiments are selected and described in this specification to better explain the principles and practical applications of the present application. The present application is limited only by the claims and all the scopes and equivalents thereof.

1. A display panel, comprising:
a substrate, comprising a base substrate, a third insulation layer formed with a communication hole, and a drive circuit located between the base substrate and the third insulation layer;
a pixel defining layer disposed on one side of the substrate, the pixel defining layer comprising at least one pixel defining portion and at least one raised portion connected to the at least one pixel defining portion, the pixel defining portion and the raised portion jointly enclosing at least one pixel opening, and the raised portion being located on a side of the pixel defining portion facing the pixel opening; and
a light-emitting device comprising a first electrode, the first electrode being located on a side of the pixel defining layer facing the substrate and being at least partially exposed from the pixel opening,
wherein the communication hole is located at least partially below the raised portion, and the first electrode is electrically connected to the drive circuit through the communication hole.

2. The display panel according to claim 1, wherein the communication hole is located partially below the pixel defining portion.

3. The display panel according to claim 1, wherein a first edge, a second edge, a third edge and a fourth edge are provided on the side of the pixel defining portion facing the pixel opening, wherein the first edge and the third edge are opposite in a first direction, the second edge and the fourth edge are opposite in a second direction, the raised portion is connected between the first edge and the second edge, and the first direction, the second direction and a thickness direction of the display panel intersect pairwise.

4. The display panel according to claim 3, wherein the at least one pixel opening comprises a plurality of pixel openings, the plurality of pixel openings are arranged at intervals in the first direction, and the plurality of pixel openings are arranged at intervals in the second direction;
at least one orthographic projection of at least one of the first edge, the second edge, the third edge and the fourth edge on the substrate is linear; and
the first edge and the third edge extend in the second direction, and the second edge and the fourth edge extend in the first direction.

5. The display panel according to claim 3, wherein the at least one pixel opening comprises a first main opening portion and an extension opening portion which is located on a peripheral side of the first main opening portion and protrudes toward the pixel defining portion, the extension opening portion communicating with the first main opening portion, and the extension opening portion being located between the second edge, the third edge and the raised portion.

6. The display panel according to claim 3, wherein a fifth edge and a sixth edge connected to each other are provided on a side of the raised portion facing the pixel opening, wherein the fifth edge is connected to the first edge, the sixth edge is connected to the second edge, and at least part of the fifth edge extends in a direction that intersects an extension direction of the second edge; and
at least part of the fifth edge extends in a direction that forms a minimum included angle of no more than 45° with the extension direction of the second edge.

7. The display panel according to claim 6, wherein the fifth edge comprises a first sub-edge and a second sub-edge connected to each other, wherein the first sub-edge is connected to the first edge, the second sub-edge is connected to the sixth edge, an orthographic projection of the first sub-edge on the substrate is arc-shaped, an orthographic projection of the second sub-edge on the substrate is linear, and the second sub-edge extends in a direction that intersects the extension direction of the second edge; and
the second sub-edge extends in a direction that forms a minimum included angle of no more than 45° with the extension direction of the second edge.

8. The display panel according to claim 6, wherein the sixth edge comprises a third sub-edge and a fourth sub-edge connected to each other, the third sub-edge being connected to the fifth edge; and the fourth sub-edge is connected to the second edge, an orthographic projection of the third sub-edge on the substrate is arc-shaped, an orthographic projection of the fourth sub-edge on the substrate is arc-shaped, and the second sub-edge extends in a direction that intersects the extension direction of the second edge.

9. The display panel according to claim 1, wherein the at least one pixel opening comprises a first sub-opening and a second sub-opening, an area of the first opening being smaller than an area of the second opening; a dimension of the raised portion on a peripheral side of the first opening in a first direction is smaller than a dimension of the raised portion on a peripheral side of the second opening in the first direction, and a dimension of the raised portion on the peripheral side of the first opening in a second direction is smaller than a dimension of the raised portion on the peripheral side of the second opening in the second direction; and the first direction, the second direction and a thickness direction of the display panel intersect pairwise.

10. The display panel according to claim 9, wherein the at least one pixel opening further comprises a third opening, the area of the second opening being smaller than an area of the third opening; the dimension of the raised portion on the peripheral side of the second opening in the first direction is smaller than a dimension of the raised portion on a peripheral side of the third opening in the first direction, and the dimension of the raised portion on the peripheral side of the second opening in the second direction is smaller than a dimension of the raised portion on the peripheral side of the third opening in the second direction;
the light-emitting device comprises a first type of device arranged corresponding to the first opening, a second type of device arranged corresponding to the second opening, and a third type of device arranged corresponding to the third opening, wherein light-emitting colors of the first type of device, the second type of device and the third type of device are pairwise distinct; and
the light-emitting color of the first type of device is red, the light-emitting color of the second type of device is green, and the light-emitting color of the third type of device is blue.

11. The display panel according to claim 1, wherein the display panel further comprises an isolation structure disposed on a side of the pixel defining layer facing away from the substrate, the isolation structure enclosing at least one isolation opening in communication with the at least one pixel opening;
the light-emitting device further comprises a light-emitting unit disposed on a side of the first electrode facing away from the substrate and a second electrode disposed on a side of the light-emitting unit facing away from the substrate, a material of the isolation structure comprises a conductive material, and the second electrode is connected to the isolation structure;
the isolation structure comprises a first isolation portion and a second isolation portion on a side of the first isolation portion facing away from the substrate, the second isolation portion protruding from the first isolation portion toward the isolation opening; and
the isolation structure further comprises a conductive portion located on a side of the first isolation portion facing the substrate, the conductive portion protruding from the first isolation portion toward the isolation opening, and the second electrode being connected to the conductive portion.

12. The display panel according to claim 11, wherein the communication hole is located below the isolation opening; and
the isolation opening comprises a second main opening portion and a clearance opening portion which is located on a peripheral side of the second main opening portion and protrudes toward the isolation structure, the clearance opening portion communicating with the main opening portion and being located above the raised portion, and the communication hole being located below the clearance opening portion.

13. A display panel, comprising:
a substrate;
a pixel defining layer disposed on one side of the substrate, the pixel defining layer comprising a pixel defining portion, wherein the pixel defining portion encloses a pixel opening, and the pixel opening comprises a first main opening portion and an extension opening portion which is located on a peripheral side of the first main opening portion and protrudes toward the pixel defining portion, the extension opening portion communicating with the first main opening portion; and
a light-emitting device comprising a first electrode partially exposed from the pixel opening.

14. The display panel according to claim 13, wherein the extension opening portion is located on a side of the first main opening portion in a second direction, the substrate located below the pixel defining layer on a side of the extension opening portion in a first direction is formed with a communication hole, part of the first electrode is located in the communication hole, and the first direction, the second direction and a thickness direction of the display panel intersect pairwise; and
a plurality of pixel openings are provided, the plurality of pixel openings are arranged at intervals in the first direction, and the plurality of pixel openings are arranged at intervals in the second direction.

15. The display panel according to claim 13, wherein the pixel defining layer further comprises a raised portion connected to an edge on a side of the pixel defining portion facing the pixel opening, the pixel defining portion and the raised portion jointly enclose the pixel opening, the raised portion protrudes from the pixel defining portion toward the pixel opening, and the extension opening portion is located on a peripheral side of the raised portion; and
the substrate comprises a base substrate, a third insulation layer formed with a communication hole, and a drive circuit located between the base substrate and the third insulation layer, wherein the communication hole is located at least partially below the raised portion, and the first electrode is electrically connected to the drive circuit through the communication hole.

16. The display panel according to claim 15, wherein a first edge, a second edge, a third edge and a fourth edge are provided on the side of the pixel defining portion facing the pixel opening, wherein the first edge and the third edge are opposite in a first direction, the second edge and the fourth edge are opposite in a second direction, the raised portion is connected between the first edge and the second edge, and the first direction, the second direction and a thickness direction of the display panel intersect pairwise;
at least one orthographic projection of at least one of the first edge, the second edge, the third edge and the fourth edge on the substrate is linear;
the first edge and the third edge extend in the second direction, and the second edge and the fourth edge extend in the first direction; and
the extension opening portion is located between the second edge, the third edge and the raised portion.

17. The display panel according to claim 16, wherein a fifth edge and a sixth edge connected to each other are provided on a side of the raised portion facing the pixel opening, wherein the fifth edge is connected to the first edge, the sixth edge is connected to the second edge, and at least part of the fifth edge extends in a direction that intersects an extension direction of the second edge; and
at least part of the fifth edge extends in a direction that forms a minimum included angle of no more than 45° with the extension direction of the second edge.

18. The display panel according to claim 13, wherein the display panel further comprises an isolation structure disposed on a side of the pixel defining layer facing away from the substrate, the isolation structure enclosing an isolation opening in communication with the pixel opening;
the light-emitting device further comprises a light-emitting unit disposed on a side of the first electrode facing away from the substrate and a second electrode disposed on a side of the light-emitting unit facing away from the substrate, a material of the isolation structure comprises a conductive material, and the second electrode is electrically connected to the isolation structure;
the isolation structure comprises a first isolation portion and a second isolation portion on a side of the first isolation portion facing away from the substrate, the second isolation portion protruding from the first isolation portion toward the isolation opening; and
the isolation structure further comprises a conductive portion located on a side of the first isolation portion facing the substrate, the conductive portion protruding from the first isolation portion toward the isolation opening, and the second electrode being connected to the conductive portion.

19. The display panel according to claim 18, wherein the communication hole is located below the isolation opening; and
the isolation opening comprises a second main opening portion and a clearance opening portion which is located on a peripheral side of the second main opening portion and protrudes toward the isolation structure, the clearance opening portion communicating with the main opening portion and being located on a peripheral side of the extension opening portion, and the communication hole being located below the clearance opening portion; and
a projection of the communication hole in a thickness direction of the display panel is spaced apart from a projection of the isolation structure in the thickness direction of the display panel.

20. A display device, comprising:
a display panel, comprising:
a substrate, comprising a base substrate, a third insulation layer formed with a communication hole, and a drive circuit located between the base substrate and the third insulation layer;
a pixel defining layer disposed on one side of the substrate, the pixel defining layer comprising at least one pixel defining portion and at least one raised portion connected to the at least one pixel defining portion, the pixel defining portion and the raised portion jointly enclosing at least one pixel opening, and the raised portion being located on a side of the pixel defining portion facing the pixel opening; and
a light-emitting device comprising a first electrode, the first electrode being located on a side of the pixel defining layer facing the substrate and being at least partially exposed from the pixel opening,
wherein the communication hole is located at least partially below the raised portion, and the first electrode is electrically connected to the drive circuit through the communication hole.
